(19) United States
(12) Patent Application Publication
(10) Pub. No.: US 2006/0049034 A1
(43) Pub. Date: Mar. 9, 2006

(54) Laser ablation apparatus and method of preparing nanoparticles using the same

(75) Inventors: Joo-hyun Lee, Seoul (KR); Yoon-ho Khang, Gyeonggi-do (KR)

Correspondence Address: BUCHANAN INGERSOLL PC;(INCLUDING BURNS, DOANE, SWECKER & MATHIS), POST OFFICE BOX 1404, ALEXANDRIA, VA, 22313-1404, US

(73) Assignee: Samsung Electronics Co., Ltd., Gyeonggi-do (KR)

(21) Appl. No.: 11/133,172

(22) Filed: May 20, 2005

(30) Foreign Application Priority Data
Sep. 4, 2004 (KR) 10-2004-0070619

(51) Int. Cl. C23C 14/00

(52) U.S. Cl. 204/192.12; 204/298.02

(57) ABSTRACT

A laser ablation apparatus and a method of preparing nanoparticles using the same are provided. The laser ablation apparatus may include: a reaction chamber having a discharge space therein; a susceptor on which a target is mounted, disposed inside the reaction chamber; a laser generator causing a plasma discharge by sputtering the target with a laser beam so as to generate positive charges and negative charges in the discharge space; and a high voltage generator attracting the negative charges generated by the plasma discharge to a predetermined position exposed to the plasma discharge by applying a positive bias voltage at the predetermined position.

### BACKGROUND

This application claims the benefit of Korean Patent Application No. 10-2004-0070619, filed on Sep. 4, 2004, in the Korean Intellectual Property Office, the disclosure of which is incorporated herein in its entirety by reference.

1. Field of the Invention

The present invention relates to a laser ablation apparatus that can readily control a particle size distribution of nanoparticles while producing nanoparticles and a method of preparing uniform nanoparticles using the same.

2. Description of the Related Art

Conventional methods used for preparing nanoparticles include pyrolysis, a laser ablation method, and the like.

Pyrolysis is a method of preparing nanoparticles using a precursor. The precursor is pyrolyzed in a reactor to grow nanoparticles. This method is relatively simple and sizes of the nanoparticles can be easily controlled. However, the sizes of the nanoparticles are dependent on a concentration of the precursor, and the concentration of the precursor must be low in order to prepare small sized nanoparticles. Thus, when using pyrolysis, a small number of nanoparticles is produced due to a low concentration of the precursor.

In the laser ablation method, a target in a bulk or aerosol powder form is sputtered with a laser beam to obtain nanoparticles. It is difficult to control the sizes of nanoparticles using this method since it takes only several nano seconds to produce nanoparticles from laser sputtering. Thus, the resulting nanoparticles have nonuniform sizes and a deviation of the particle size distribution is large. In this method, a subsequent process for providing a uniform particle size distribution of the nanoparticles is required. As a result, the process for preparing nanoparticles becomes complicated. Further, it is difficult to discriminate particles in the subsequent process and a very small number of nanoparticles are discriminated from the resulting particles, thus resulting in low product yield.

U.S. Pat. No. 5,585,020 discloses a method of preparing nanoparticles by irradiating Si powder aerosol with a laser. This method results in nanoparticles with nonuniform sizes and a very broad particle size distribution.

U.S. Pat. No. 6,230,572 discloses an apparatus for reducing the particle size distribution of the resulting nanoparticles by discriminating nanoparticles according to electrical mobility, which depends on particle size. However, in this apparatus, although the particle size distribution of the resulting nanoparticles can be reduced, a very small number of nanoparticles is discriminated from the resulting particles, thus resulting in low product yield.

### SUMMARY

Embodiments of the present invention provide a laser ablation apparatus that can readily control the particle size distribution of nanoparticles while producing nanoparticles and a method of preparing uniform nanoparticles using the same.

According to an aspect of an embodiment of the present invention, there is provided a laser ablation apparatus including: a reaction chamber having a discharge space therein; a susceptor on which a target is mounted, disposed inside the reaction chamber; a laser generator causing a plasma discharge by sputtering the target with a laser beam to generate positive charges and negative charges in the discharge space; and a high voltage generator attracting the negative charges generated by the plasma discharge to a predetermined position exposed to the plasma discharge by applying a positive bias voltage at the predetermined position.

The high voltage generator may include a conductor exposed to the plasma discharge and can attract the negative charges through the conductor. The positive bias voltage may be in the range of about 1 to about 100,000 V. An insulating layer may be formed on the surface of the conductor. An energy density of the laser beam may be about 0.1 to about 10 J/cm². An inert gas that prevents collision between the positive charges may be supplied to the reaction chamber when plasma discharge occurs.

The laser ablation apparatus may further include a vacuum pump that maintains the inside of the reaction chamber at a low pressure and an analysis device that analyzes the characteristics of the particles prepared in the reaction chamber. Both the vacuum pump and the analysis device may be connected to the reaction chamber.

The laser ablation apparatus may further include a carrier gas supply device that supplies to the reaction chamber a carrier gas carrying particles prepared in the reaction chamber outside the reaction chamber. The carrier gas supply device may be connected to the reaction chamber. The carrier gas supply device supplies the carrier gas to the reaction chamber when the plasma discharge occurs.

The laser ablation apparatus may further include a heat treatment device that heat treats particles prepared in the reaction chamber. The heat treatment device is connected to the reaction chamber. The heat treatment is performed under an O₂, O₃, H₂O, NH₃ or H₂ atmosphere.

The laser ablation apparatus may further include an analysis device that analyzes the characteristics of the heat treated particles. The analysis device may be connected to the heat treatment device.

According to another aspect of the present invention, there may be provided a method of preparing nanoparticles, the method including: providing a target in a reaction chamber having a discharge space; causing plasma discharge by sputtering the target with a laser beam to generate positive charges and negative charges in the discharge space; and applying a positive bias voltage at a predetermined position exposed to the plasma discharge so as to attract the negative charges generated by the plasma discharge to the predetermined position.

A conductor may be provided at the predetermined position exposed to the plasma discharge. The conductor attracts the negative charges if a positive bias voltage is applied thereto. The positive bias voltage may be in the range of about 1 to about 100,000 V, and an energy density of the laser beam may be about 0.1 to about 10 J/cm². An insulating layer may be formed on the surface of the conductor. The inside of the reaction chamber may be maintained at a low pressure when the plasma discharge occurs. An inert gas that prevents collision between the positive charges may be supplied to the reaction chamber when the plasma discharge occurs.

A carrier gas that carries particles prepared in the reaction chamber outside the reaction chamber may be supplied to the reaction chamber when the plasma discharge occurs.

The method of preparing nanoparticles may further include heat treating particles prepared in the reaction chamber under an O₂, O₃, H₂O, NH₃ or H₂ atmosphere.

### BRIEF DESCRIPTION OF THE DRAWINGS

The above and other features and advantages of the present invention will become more apparent by describing in detail exemplary embodiments thereof with reference to the attached drawings in which:

FIG. 1 is a schematic cross-sectional view of a laser ablation apparatus according to an embodiment of the present invention;

FIG. 2 is a schematic cross-sectional view of a laser ablation apparatus according to another embodiment of the present invention; and

FIGS. 3A and 3B are SEM images of surfaces of substrates to which nanoparticles prepared according to a Comparative Example and an Example of the present invention, respectively, are deposited.

### DETAILED DESCRIPTION OF EXEMPLARY EMBODIMENTS OF THE INVENTION

Hereinafter, a laser ablation apparatus and a method of preparing nanoparticles using the same according to embodiments of the present invention will be described in detail with reference to the attached drawings.

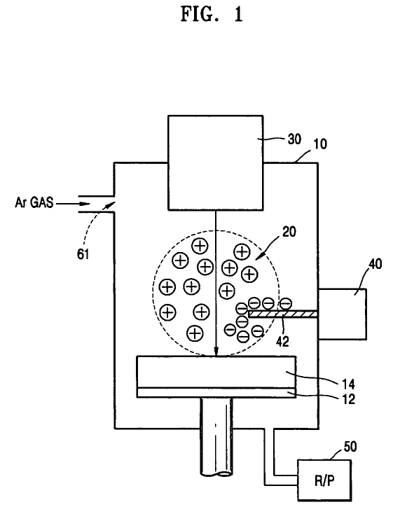

FIG. 1 is a schematic cross-sectional view of a laser ablation apparatus according to an embodiment of the present invention.

Referring to FIG. 1, the laser ablation apparatus may include a reaction chamber 10, a laser generator 30, a high voltage generator 40 and a vacuum pump 50.

A susceptor 12 having a target 14 mounted thereon may be located inside the reaction chamber 10 and the laser generator 30 may be located above the susceptor 12. Plasma discharge occurs between the susceptor 12 and the laser generator 30. The high voltage (HV) generator 40 may be attached to a side of the reaction chamber 10 and includes a conductor 42 exposed to plasma discharge. The vacuum pump 50 may be connected to the reaction chamber 10 and a gas inlet 61 may be provided at a side of the reaction chamber 10.

The target 14 may be a material that will be transformed into nanoparticles and can be almost any solid material in a bulk form or powder form. Examples of the target 14 include metals such as Au, Ni, Cu, etc., and oxides such as MgO, Cao, etc. Other solid materials besides these materials can be used as the target 14.

The reaction chamber 10 may have a discharge space 20 therein and the inside of the reaction chamber 10 may be maintained at a low pressure of about 3 to about 10 torr, for example, by a rotary pump.

The laser generator 30 may cause plasma discharge by sputtering the target 14 mounted on the susceptor 12 with a laser beam so as to generate positive charges and negative charges in the discharge space 20. The susceptor 12 can rotate at about 8 to about 10 rpm.

The HV generator 40 attracts the negative charges generated by the plasma discharge to a predetermined position exposed to the plasma discharge by applying a positive bias voltage at the predetermined position. The HV generator 40 includes the conductor 42 exposed to the plasma discharge and attracts negative charges with the conductor 42. The positive bias voltage may be in the range of about 1 to about 100,000 V. The conductor 42 can have an insulating layer (not shown) on the surface thereof. The insulating layer may be composed of Teflon, an oxide, or another insulating material.

If the positive bias voltage is applied to the conductor 42 when plasma discharge occurs, a plurality of negative charges in the discharge space 20 may be attracted to the conductor 42. Thus, a plurality of positive charges remain in the discharge space 20 and the growth of nanoparticles may be prevented due to repulsion between positive charges, thereby controlling sizes of nanoparticles while producing nanoparticles. Thus, due to the application of the positive bias voltage, fine and uniform nanoparticles can be prepared and a particle size distribution can be narrowed.

In the laser ablation apparatus of the present embodiment, the particle size distribution of nanoparticles can be readily controlled while producing the nanoparticles. That is, nanoparticles prepared by the laser ablation apparatus of the present embodiment may have uniform sizes and the particle size distribution may be small.

Thus, a separate subsequent process for reducing the particle size distribution of the resulting particles is not required and nanoparticles with fine and uniform sizes may be prepared in one process.

A method of preparing nanoparticles using the laser ablation apparatus will now be described in detail with reference to FIG. 1.

First, the target 14 that will be transformed into nanoparticles may be mounted on the susceptor 12 in the reaction chamber 10 having the discharge space 20. Then, an inert gas, for example, Ar gas, may be supplied to the reaction chamber 10 at a flow rate of about 0.5 to about 1 L/min through the gas inlet 61. The inside of the reaction chamber 10 may be maintained at a low pressure of about 3 to about 10 torr by the vacuum pump 50.

The target 14 may be sputtered by the laser beam generated by the laser generator 30 so that plasma discharge occur to generate positive charges and negative charges in discharge space 20. Positive ions include Si¹⁺, Si²⁺, Si³⁺, and Si⁴⁺ and electrons may be generated as the negative charges. When plasma discharge occurs, a plurality of positive charges and negative charges may be generated in the discharge space 20 and complicated electrical reactions occur in the discharge space 20. An energy density of the laser beam may be about 0.1 to about 10 J/cm², and preferably about 2 to about 4 J/cm². The laser can be a general laser that can sputter the target 14, for example, a 248 nm KrF excimer laser.

In the main process by which the nanoparticles are prepared, a plurality of positive charges may be generated from the target 14 during the laser sputtering and the positive charges collide and bond with one another to grow a nanoparticle. As collision frequency increases, the nanoparticle grows larger. However, since it takes only several nano seconds to produce nanoparticles from laser sputtering, it may be difficult to control sizes of nanoparticles. Conventionally, a process for reducing particle size distribution of nanoparticles produced may be separately performed to obtain nanoparticles with a uniform particle size distribution.

According to the method of the present embodiment, a positive bias voltage may be applied at a predetermined position exposed to the plasma discharge to attract negative charges generated by the plasma discharge to the predetermined position. For example, the conductor 42 may be located in the predetermined position exposed to the plasma discharge and if the positive bias voltage is applied to the conductor 42 by the HV generator 40, the conductor 42 can attract the negative charges. The positive bias voltage is in the range of 1-100,000 V.

If the positive bias voltage is applied to the conductor 42 when the plasma discharge occurs, a plurality of negative charges in the discharge space 20 may be attracted to the conductor 42. Thus, a plurality of positive charges remain in the discharge space 20 and the growth of nanoparticles may be prevented due to repulsion between positive charges, thereby controlling sizes of nanoparticles while producing nanoparticles. Thus, due to the application of the positive bias voltage to the conductor 42 exposed to the plasma discharge, fine and uniform nanoparticles can be prepared and the particle size distribution can be narrowed. Preferably, the conductor 42 can have an insulating layer (not shown) on the surface thereof. The insulating layer may be composed of Teflon, an oxide, or another insulating material.

The inert gas, for example, Ar gas, supplied to the reaction chamber 10 can prevent collision between the positive charges when the plasma discharge occurs. That is, the inert gas prevents collision between the positive charges to interrupt the growth of nanoparticles.

A carrier gas that carries the nanoparticles prepared in the reaction chamber 10 outside the reaction chamber 10 can be supplied to the reaction chamber 10 when the plasma discharge occurs. The carrier gas may be an inert gas, for example, Ar or He. When the carrier gas is an inert gas, the carrier gas can prevent the growth of nanoparticles as well as carry the nanoparticles.

The nanoparticles prepared by the method of the present embodiment have diameters of 1-20 nm and a uniform particle size distribution.

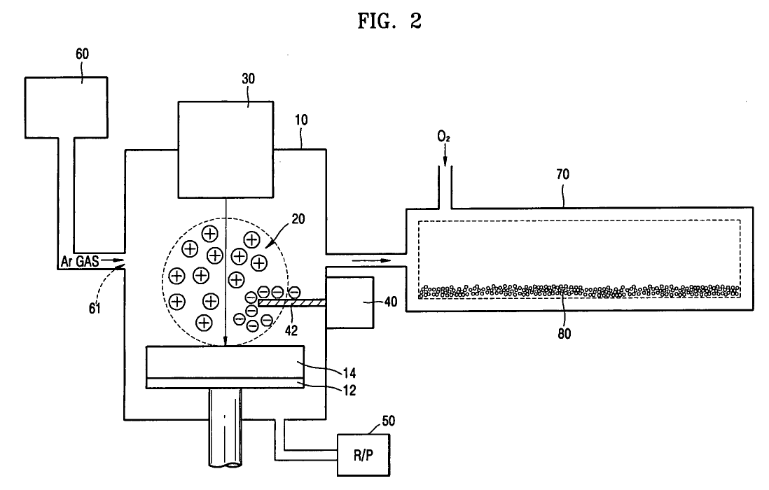

The method of preparing nanoparticles of the present embodiment can further include heat treating nanoparticles prepared in the furnace 70 in FIG. 2. The heat treatment may be performed under an O₂, O₃, H₂O, NH₃ or H₂ atmosphere. Due to the heat treatment, an oxide layer, nitride oxide or hydrogen oxide may be formed on surfaces of particles 80. A heat treatment temperature can be 1050° C.

FIG. 2 is a schematic cross-sectional view of a laser ablation apparatus according to another embodiment of the present invention. Only elements of the apparatus of the present embodiment different from those of the embodiment of FIG. 1 will now be described. Also, in the drawings, like reference numbers refer to like elements.

Referring to FIG. 2, the laser ablation apparatus further includes a carrier gas supply device 60 providing a carrier gas carrying particles prepared in the reaction chamber 10 outside the reaction chamber 10, for example, to a heat treatment device 70. The carrier gas supply device may be connected to the reaction chamber 10. The carrier gas can be an inert gas, for example, Ar or He gas. When the carrier gas is an inert gas, the carrier gas can prevent reactions between the positive charged particles as well as carry particles prepared in the reaction chamber 10 when plasma discharge occurs.

The laser ablation apparatus may further include the heat treatment device 70 in which particles 80 prepared in the reaction chamber 10 are heat treated. The heat treatment device 70 may be connected to the reaction chamber 10. O₂, O₃, H₂O, NH₃ or H₂ may be supplied to the heat treatment device 70. Thus, the heat treatment may be performed under an O₂, O₃, H₂O, NH₃ or H₂ atmosphere and an oxide layer, nitride layer or hydrogen layer is formed on surfaces of the particles 80 in the heat treatment. A heat treatment temperature can be 1050° C.

The laser ablation apparatus can further include an analysis device (not shown) that analyzes the characteristics of the heat treated particles 80, for example, sizes or constituents of the particles 80. The analysis device can be connected to the heat treatment device 70. The analysis device may also be directly connected to the reaction chamber 10 to analyze the characteristics of particles prepared in the reaction chamber 10.

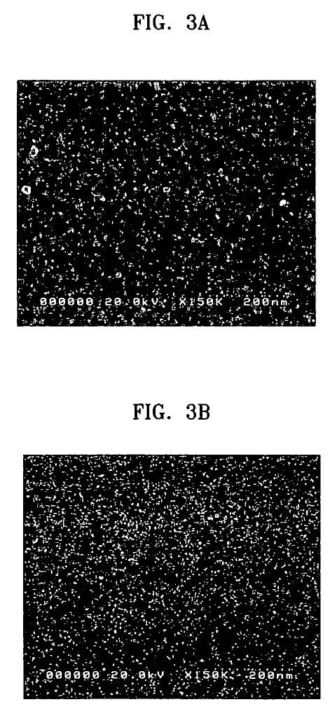

FIGS. 3A and 3B are SEM images showing surfaces of substrates to which nanoparticles prepared according to a Comparative Example and an Example of the present invention, respectively, are deposited.

The nanoparticles shown in FIG. 3A were prepared under the following conditions: an internal pressure of the reaction chamber of 3 torr, a flow rate of Ar gas supplied to the reaction chamber of 0.5 L/min, a flow rate of O₂ supplied to the heat treatment device of 0.5 L/min, laser beam density of 2.4 J/cm², and a heat treatment temperature of 1050° C.

The nanoparticles shown in FIG. 3B were prepared under the same conditions as the nanoparticles shown in FIG. 3A, except that a positive bias voltage of 200 V was applied at a predetermined position by the HV generator when the plasma discharge occurred.

Referring to FIGS. 3A and 3B, nanoparticles of FIG. 3B had uniform sizes. Geometric standard deviations of nanoparticles of FIGS. 3A and 3B were 1.52 and 1.34, respectively.

According to the laser ablation apparatus and the method of preparing nanoparticles using the same of embodiments of the present invention, a particle size distribution of nanoparticles can be readily controlled while producing nanoparticles. That is, nanoparticles prepared according to the method of an embodiment of the present invention have uniform sizes and a small particle size distribution.

Thus, unlike conventional methods, a separate subsequent process for reducing a particle size distribution of the resulting nanoparticles is not required and nanoparticles with fine and uniform sizes are prepared in one process. That is, the production process is simplified.

In addition, due to the simplified production process, the cost of preparing nanoparticles may be reduced and the product yield may be increased.

The present invention relates to a method of preparing nanoparticles, which can be applied to the preparation of an internal electrode material of electrical devices such as multi layer ceramic capacitor (MLCC), a conductor material, a nanocrystal memory device or nanocrystal electroluminescence (EL) device, and the like.

While the present invention has been particularly shown and described with reference to exemplary embodiments thereof, it will be understood by those of ordinary skill in the art that various changes in form and details may be made therein without departing from the spirit and scope of the present invention as defined by the following claims.

What is claimed is:

1. A laser ablation apparatus comprising:
a reaction chamber having a discharge space therein;
a susceptor on which a target is mounted, disposed inside the reaction chamber;
a laser generator causing a plasma discharge by sputtering the target with a laser beam to generate positive charges and negative charges in the discharge space; and
a high voltage generator attracting the negative charges generated by the plasma discharge to a predetermined position exposed to the plasma discharge by applying a positive bias voltage at the predetermined position.

2. The laser ablation apparatus of claim 1, wherein the positive bias voltage is in the range of about 1 to about 100,000 V.

3. The laser ablation apparatus of claim 1, wherein the high voltage generator includes a conductor exposed to the plasma discharge.

4. The laser ablation apparatus of claim 3, wherein the high voltage generator attracts the negative charges with the conductor.

5. The laser ablation apparatus of claim 3, further comprising an insulating layer formed on the surface of the conductor.

6. The laser ablation apparatus of claim 1, further comprising a vacuum pump that is connected to the reaction chamber and maintains the inside of the reaction chamber at a low pressure.

7. The laser ablation apparatus of claim 1, further comprising a carrier gas supply device that is connected to the reaction chamber and supplies to the reaction chamber a carrier gas carrying particles prepared in the reaction chamber outside the reaction chamber.

8. The laser ablation apparatus of claim 1, wherein an inert gas that prevents collision between the positive charges is supplied to the reaction chamber when the plasma discharge occurs.

9. The laser ablation apparatus of claim 1, further comprising a heat treatment device that is connected to the reaction chamber and heat treats particles prepared in the reaction chamber.

10. The laser ablation apparatus of claim 9, wherein the heat treatment is performed under an O₂, O₃, H₂O, NH₃ or H₂ atmosphere.

11. The laser ablation apparatus of claim 9, further comprising an analysis device that is connected to the heat treatment device and analyzes characteristics of the heat treated particles.

12. The laser ablation apparatus of claim 1, further comprising an analysis device that is connected to the reaction chamber and analyzes characteristics of particles prepared in the reaction chamber.

13. The laser ablation apparatus of claim 1, wherein an energy density of the laser beam is about 0.1 to about 10 J/cm².

14. A method of preparing nanoparticles, the method comprising:
providing a target in a reaction chamber having a discharge space;
causing plasma discharge by sputtering the target with a laser beam so as to generate positive charges and negative charges in the discharge space; and
applying a positive bias voltage at a predetermined position exposed to the plasma discharge so as to attract the negative charges generated by the plasma discharge to the predetermined position.

15. The method of claim 14, wherein the positive bias voltage is in the range of about 1 to about 100,000 V.

16. The method of claim 14, wherein a conductor is disposed at the predetermined position exposed to the plasma discharge and the positive bias voltage is applied to the conductor.

17. The method of claim 16, wherein the conductor attracts the negative charges.

18. The method of claim 16, wherein an insulating layer is formed on the surface of the conductor.

19. The method of claim 14, wherein a carrier gas that carries particles prepared in the reaction chamber outside the reaction chamber is supplied to the reaction chamber when the plasma discharge occurs.

20. The method of claim 14, further comprising heat treating particles prepared in the reaction chamber.

21. The method of claim 20, wherein the heat treatment is performed under an O₂, O₃, H₂O, NH₃ or H₂ atmosphere.

22. The method of claim 14, wherein the inside of the reaction chamber is maintained at a low pressure when the plasma discharge occurs.

23. The method of claim 14, wherein an energy density of the laser beam is about 0.1 to about 10 J/cm².

24. The method of claim 14, wherein an inert gas that prevents collision between the positive charges is supplied to the reaction chamber when the plasma discharge occurs.
